(19) United States
(12) Patent Application Publication
(10) Pub. No.: US 2011/0005575 A1
(43) Pub. Date: Jan. 13, 2011

(54) Back reflector for photovoltaic devices

(75) Inventor: Xinmin Cao, Sylvania, OH (US)

Correspondence Address: Emch, Schaffer, Schaub & Porcello, Co., L.P.A, P.O. Box 916, Toledo, OH, 43697-0916, US

(73) Assignee: Xunlight Corporation

(21) Appl. No.: 12/803,876

(22) Filed: Jul. 8, 2010

Related U.S. Application Data
(60) Provisional application No. 61/270,503, filed on Jul. 9, 2009.

(51) Int. Cl. H01L 31/052

(52) U.S. Cl. 136/246

(57) ABSTRACT

This invention relates generally to thin-film photovoltaic devices, and more specifically to an improved back reflector structure of multiple material layers for being used in thin-film photovoltaic devices. More particularly, the invention is to provide an enhanced back reflector having a texture, a high reflectivity, a high yield, and a long lifetime stability which can be applied into thin-film silicon based photovoltaic devices. The back reflector structure consists of (i) a first textured metal or alloy layer (hereinafter referred to as a first metal layer), such as aluminum (Al), formed on a metal (such as stainless steel) or polymer (such as Kapton) substrate, (ii) a thin oxide or nitride barrier layer (hereinafter referred to as a first barrier layer), such as zinc oxide (ZnO), formed on the first metal layer, (iii) a second reflective metal or alloy layer (hereinafter referred to as a second metal layer), such as silver (Ag), formed on the first barrier layer, (iv) a transparent oxide or nitride barrier layer (hereinafter referred to as a second barrier layer), such as zinc oxide, formed on the second metal layer.

This application claims the benefit of provisional patent application No. 61/270,503 filed Jul. 9, 2009.

### FIELD OF THE INVENTION

This invention relates generally to thin-film photovoltaic devices, and more specifically to an improved back reflector structure of multiple material layers for use in thin-film photovoltaic devices. More particularly, the invention is to provide an enhanced back reflector having a texture, a high reflectivity, a high yield, and a long lifetime stability which can be applied into thin-film silicon based photovoltaic devices.

### BACKGROUND OF THE INVENTION

Thin-film photovoltaic devices, which can be produced by forming the so-called thin-film semiconductor solar cell materials, such as thin-film silicon based a-Si, a-SiGe, nc-Si or μe-Si layers, CdS/CdTe, and CdS/CuInSe₂ layers, etc., on low-cost substrates such as glass, stainless steel, etc., have been intensively studied and developed in recent years. A back reflector of a high light-reflectivity is generally applied underneath the photovoltaic semiconductor layers to improve the performance of the device. A back reflector with a high texture is also conventionally applied in photovoltaic devices to supply a light diffusing reflecting surface for a better light trapping capability for a further device efficiency improvement. A back reflector reflects and/or diffuses the portion of sunlight that has passed through but has not absorbed yet, back into the semiconductor layers for further absorption.

FIG. 1 illustrates a state of the art a-Si (amorphous silicon) based thin-film solar cell device made on a metal substrate coated with conventional smooth back reflector with high reflectivity. The solar cell device 100 consists of a metal substrate 101, such as a stainless steel foil, for an electric back contact and device support, a back reflector 102 comprising a highly reflective and smooth metal layer 103 and a transparent and conductive oxide (TCO) buffer layer 104, an a-Si based semiconductor solar material 105, a front contact TCO layer 106, and front contact electrode grids 107.

FIG. 2 illustrates a state of the art a-Si based thin-film solar cell device made on a metal substrate coated with highly textured back reflector with high light-scattering. The solar cell device 200 consists of a metal substrate 201, such as a stainless steel foil, for an electric back contact and device support, a back reflector 202 comprising a textured metal layer 203 and a transparent and conductive oxide (TCO) buffer layer 204, an a-Si based semiconductor solar material 205, a front contact TCO layer 206, and front contact electrode grids 207.

Several materials can be used as back reflectors in the above described structures. A pure silver layer is the most highly reflective material having an integrated total reflectivity of about 95% or higher over the wavelength range from 600 nm to 1200 nm, (U.S. Pat. No. 5,668,050 entitled Solar Cell Manufacturing Method). A copper (Cu)/ZnO BR layer gives a total reflectivity of ≧90% and an aluminum (AI)/ZnO BR layer gives a total reflectivity of only about 85% for the wavelength ranging from 600 nm to 1000 nm. A stainless steel layer would only give a total integration reflectivity of about 45%.

Prior studies also have shown that an aluminum metal layer can be produced with a textured surface at high substrate temperatures of about 300° C. However, interdiffusion between the silicon and aluminum layers can happen when a thin-film silicon material is directly deposited on an Al metal layer. A ZnO buffer layer is preferably introduced in-between the silicon layer and the Al metal reflective layer to prevent such interdiffusion.

### SUMMARY OF THE INVENTION

This invention relates to a back reflector (BR) structure of multiple material layers for use in a photovoltaic device. More particularly, the invention provides a back reflector having a texture, a high reflectivity, a high yield, and a long lifetime stability which can be applied into thin-film solar photovoltaic devices. The back reflector structure consists of (i) a first textured metal or alloy layer (hereinafter referred to as a first metal layer), such as aluminum (Al), formed on a metal (such as stainless steel) or polymer (such as Kapton) substrate, (ii) a thin oxide or nitride barrier layer (hereinafter referred to as a first barrier layer), such as zinc oxide (ZnO), formed on the first metal layer, (iii) a second reflective metal or alloy layer (hereinafter referred to as a second metal layer), such as silver (Ag), formed on the first barrier layer, (iv) a transparent oxide or nitride barrier layer (hereinafter referred to as a second barrier layer), such as zinc oxide, formed on the second metal layer.

The invention is directed to a thin-film photovoltaic device comprising a substrate and a back reflector deposited over the substrate. The back reflector has a textured metal layer, a highly-reflective metal layer, and a first barrier layer positioned between the textured layer and the high-reflective layer. A thin-film semiconductor solar material is positioned on said back reflector. A front contact TCO layer is positioned on said semiconductor material. A front contact electrode grid is positioned on said front TCO layer.

Other objects and advantages of the present invention will become apparent to those skilled in the art upon a review of the following detailed description of the preferred embodiments and the accompanying drawings.

### BRIEF DESCRIPTION OF THE DRAWINGS

FIG. 1 is a cross sectional view of a state of the art a-Si based thin-film solar cell device made on a metal substrate coated with conventional smooth back reflector of high reflectivity.

FIG. 2 is a cross sectional view of a state of the art a-Si based thin-film solar cell device made on a metal substrate coated with textured back reflector of high light-scattering.

FIG. 3 is a cross sectional view of a thin-film solar cell device made on a metal substrate coated with textured and highly-reflective back reflector according to the present invention.

FIG. 4 is a chart showing reflectivity for the back reflector of the present invention.

FIG. 5 is a chart showing reflectivity for the back reflector of the present invention.

FIG. 6 is a chart showing reflectivity for the back reflector of the present invention.

FIG. 7 is a chart showing reflectivity for the back reflector of the present invention.

FIG. 8 is a chart showing reflectivity for the back reflector of the present invention.

FIG. 9 is a chart showing reflectivity for the back reflector of the present invention.

FIG. 10 is a chart showing reflectivity for the back reflector of the present invention.

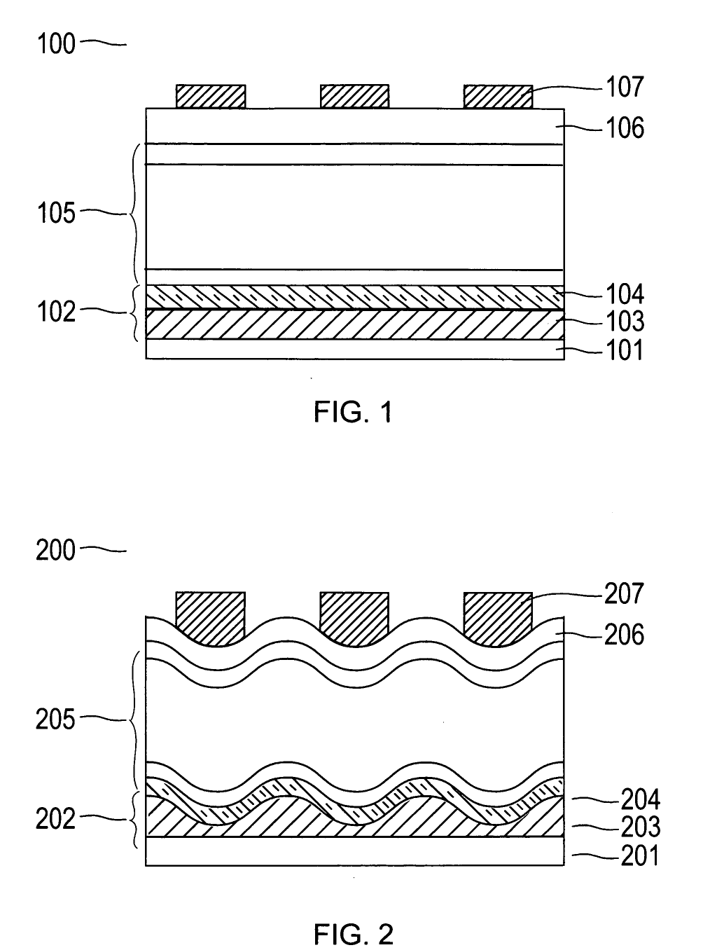

### DETAILED DESCRIPTION OF THE PREFERRED EMBODIMENT(S)

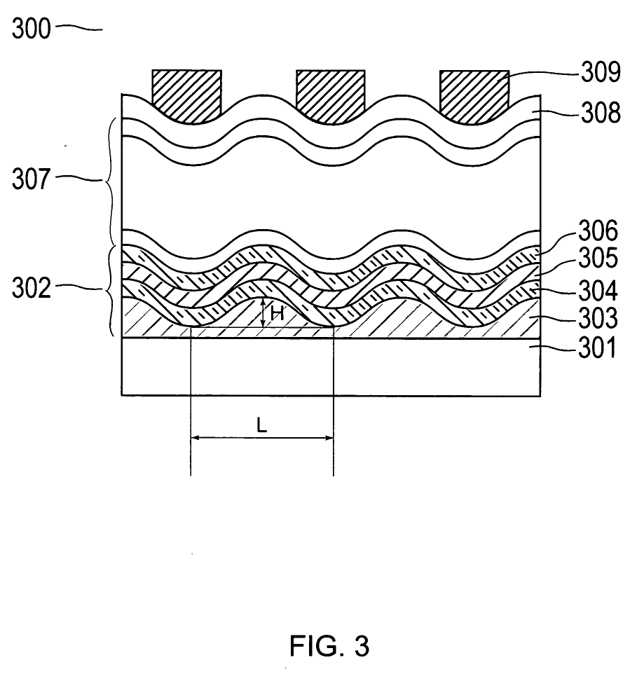

FIG. 3 illustrates a thin-film solar cell device made on a metal substrate coated with a textured and highly-reflective back reflector according to the present invention. The solar cell device 300 consists of a metal substrate 301, such as a stainless steel foil, for an electric back contact and device support, a textured and highly-reflective back reflector 302, an a-Si based semiconductor solar material 307, a front contact TCO layer 308, and front contact electrode grids 309.

The textured and highly-reflective back reflector 302 as shown in FIG. 3 comprise (i) a textured metal layer 303 made of Al with a random or periodic texture length (as marked in FIG. 3 as L) in the range from about 100 nm to about 2000 nm, and a random or periodic texture peak-valley height (as marked in FIG. 3 as H) in the range from about 50 nm to about 1000 nm; (ii) a first barrier layer 304 such as a ZnO layer with a thickness from about 10 to about 200 nm; (iii) a highly-reflective metal or alloy layer 305, such as Ag(0.7)Pd(0.1)Cu(0.2) with a thickness from about 30 to about 300 nm, formed on the first barrier layer, (iv) a second TCO barrier layer 306, such as a ZnO layer with a thickness from about 100 to about 4000 nm, formed on the second metal layer.

The first textured metal layer 303 with a random or periodic textured surface, has an average surface roughness Rₐ in the range of about 20 nm to about 1000 nm.

The back reflector structure consists of (i) a textured metal or alloy layer 303 (hereinafter referred to as a first metal layer), such as aluminum (Al), formed on a metal (such as stainless steel) or polymer (such as Kapton) substrate 301, (ii) a thin oxide or nitride barrier layer 304 (hereinafter referred to as a first barrier layer), such as zinc oxide (ZnO), formed on the first metal layer, (iii) a reflective metal or alloy layer 305 (hereinafter referred to as a second metal layer), such as silver (Ag), formed on the first barrier layer 306, (iv) a transparent conductive oxide or nitride barrier layer (hereinafter referred to as a second barrier layer), such as zinc oxide, formed on the second metal layer.

Data have shown that large-area roll-to-roll thin-film silicon solar cells made with the enhanced back-reflector of the invention with a textured and highly-reflective Al/ZnO/Ag/ZnO structure have a 10 to 15% higher efficiency in comparison to solar cells made with a conventional Al/ZnO back-reflector. One approach to improve the long term stability is to use an alloy of Ag. The metals that have been found to be preferable to be alloyed with Ag are Pd and Cu. These metals (Pd and Cu) have been shown to improve the tarnishing resistance of Ag. The addition of Pd should lower the migration of Ag into the semiconductor material as well. Key components of the back reflector based on the present invention are summarized as follows:
1. Silver gives much higher reflectivity than other metal layers, such as Al, Cu, Zn, etc. However, due to its soft nature, a silver layer is easily deformed. Deformation in the silver layer can result in the deformation of the overlying multiple solar cell layers. Such deformation can cause short circuit junctions, interlayer peeling or cracks, and low yield during the initial solar cell manufacturing process. Furthermore, a thin-film silicon solar cell with a silver back reflector (Ag BR) might have a long-term stability issue because of silver's intrinsic migration tendency when used in long-term outdoor application in a high moisture environment. An Ag BR is very reflective but is known to give poor yields for the above reasons.
2. An aluminum back reflector (Al BR) has lower reflectivity, than the Ag BR. But the Al BR has better texture characteristics, because of the low deposition temperature utilized. The Al BR also has better yields, most likely due to better adhesion with the substrate.
3. The layered back reflector structure from the present invention, such as Al/ZnO/Ag/thick ZnO, provides the best features of each material and layer; An Al layer for better texture and yields and an Ag layer for better reflection, and this layered structure results in an improved back reflector.
4. An Ag BR is also known to give poor stability under humid conditions because of Ag migration.
5. A thick ZnO layer (greater than 0.5 micron) and/or Pd alloyed with the Ag will reduce migration under humid conditions, improve stability and produce an improved back reflector. Furthermore, the Ag in the back reflector is built into a ZnO/Ag/ZnO sandwich structure which gives better hardness (lower deformability), better adhesion, lower migration, thus better yield and long term stability.

### Example 1

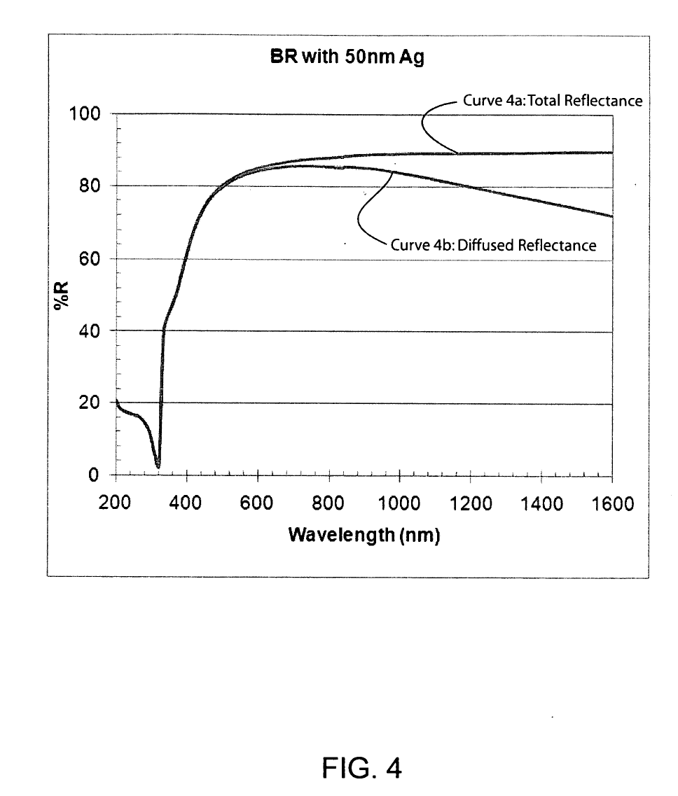

A back reflector 302 made on stainless steel (SS) foil substrate 301 has a structure as shown in FIG. 3 comprising (i) a first metal layer 303 of a textured aluminum layer of 300 nm thick with a random texture surface. This layer has a root mean square (RMS) surface roughness Rᵣₘₛ of 240 nm and a maximum peak to valley Rₚ₋ᵥ of 480 nm; (ii) a first barrier layer 304 of a ZnO layer with a thickness of 30 nm; (iii) a second metal layer 305 of a highly-reflective silver layer with a thickness of 50 nm, formed on the first barrier layer, (iv) a second TCO barrier layer 306 of a ZnO layer with a thickness of 650 nm, formed on the second metal layer. FIG. 4 shows a total reflection spectrum (Curve 4a) and a diffused reflection spectrum (Curve 4b) for a BR having the above described structure SS/300 nm-Al/30 nm-ZnO/50 nm-Ag. Curve 4a displays a high total reflectance of 80 to 88% in the wavelength range between 500 and 1000 nm, while Curve 4b displays a great diffuse reflectance of 80 to 85% in the wavelength range between 500 and 1000 nm.

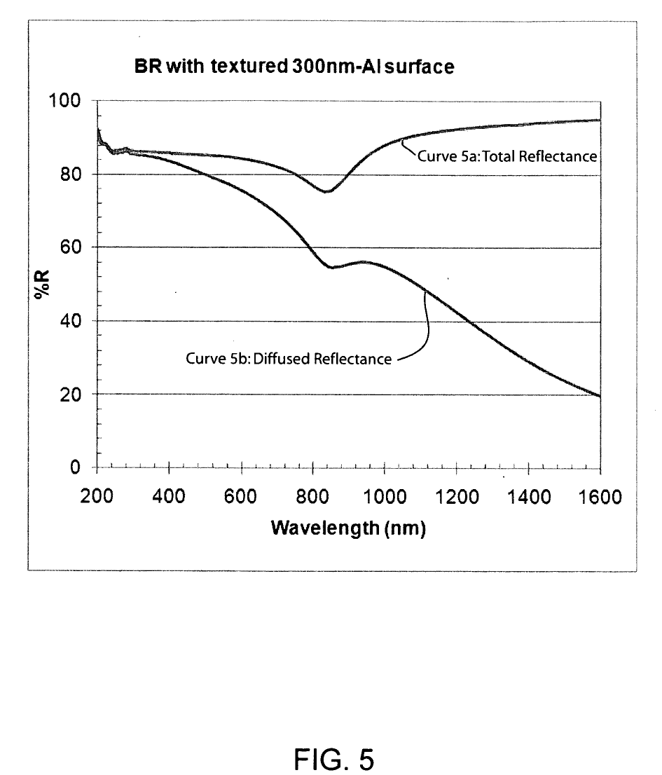

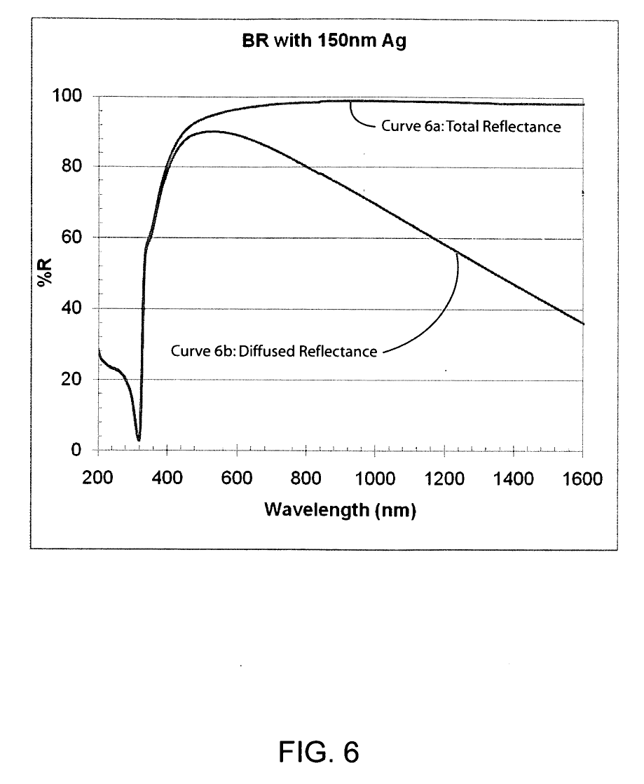

For a comparison, a total reflection spectrum (Curve 5c) and a diffused reflection spectrum (Curve 5d) for a BR having a structure of only SS/300 nm-Al layer without 30 nm-ZnO/50 nm-Ag layers is also shown in FIG. 5. For the BR having a textured Al-layer surface, Curve 5c displays a total reflectance valley in the wavelength range between 750 and 900 nm, having a minimum total reflectance of 76% at the wavelength (λ) of 832 nm; while Curve 5d displays a high diffuse reflectance of 55% at λ=832 nm.

### Example 2

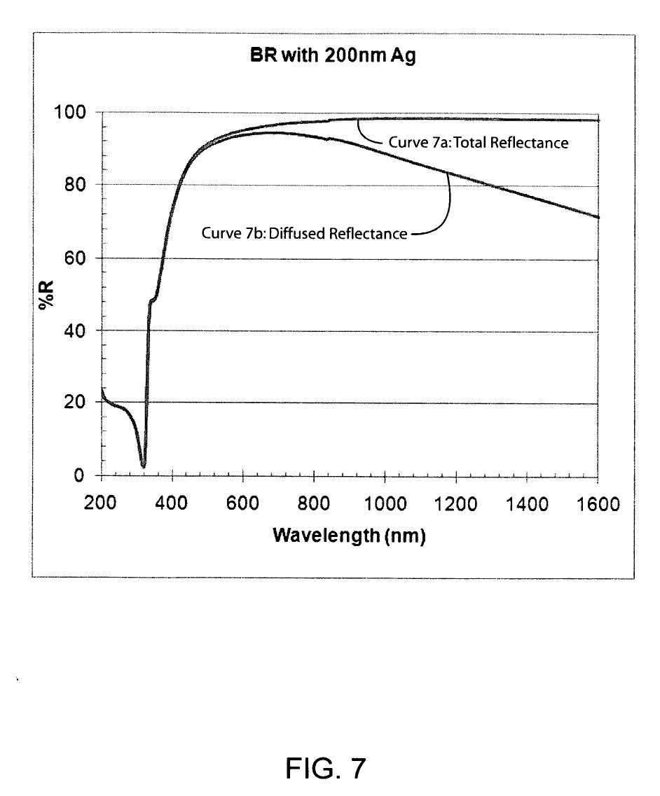

A back reflector 302 made on SS foil substrate 301 has a structure as shown in FIG. 3. comprising (i) a first metal layer 303 of a textured aluminum layer of 300 nm thick with a random texture surface same as the Al-layer in example 1; (ii) a first barrier layer 304 of a ZnO layer with a thickness of 30 nm; (iii) a second metal layer 305 of a highly-reflective silver layer with a thickness of 100 nm, formed on the first barrier layer, (iv) a second TCO barrier layer 306 of a ZnO layer with a thickness of 650 nm, formed on the second metal layer. FIG. 7 shows a total reflection spectrum (Curve 6a) and a diffused reflection spectrum (Curve 6b) for a BR having the above described structure SS/300 nm-Al/30 nm-ZnO/150 nm-Ag. Curve 6a displays a very high total reflectance of 90 to 98% in the wavelength range between 500 and 1000 nm, while Curve 6b displays a high diffuse reflectance of 88 to 70% in the wavelength range between 500 and 1000 nm.

### Example 3

A back reflector 302 made on SS foil substrate 301 has a structure as shown in FIG. 3 comprising (i) a first metal layer 303 of a textured aluminum layer of 300 nm thick with a random texture surface same as the Al-layer in example 1; (ii) a first barrier layer 304 of a ZnO layer with a thickness of 30 nm; (iii) a second metal layer 305 of a highly-reflective silver layer with a thickness of 200 nm, formed on the first barrier layer, (iv) a second TCO barrier layer 306 of a ZnO layer with a thickness of 650 nm, formed on the second metal layer. FIG. 7 shows a total reflection spectrum (Curve 7a) and a diffused reflection spectrum (Curve 7b) for a BR having the above described structure SS/300 nm-Al/30 nm-ZnO/200 nm-Ag. Curve 7a displays an excellent total reflectance of 92 to 98% in the wavelength range between 500 and 1000 nm, while Curve 7b displays a very high diffuse reflectance of 92 to 88% in the wavelength range between 500 and 1000 nm.

### Example 4

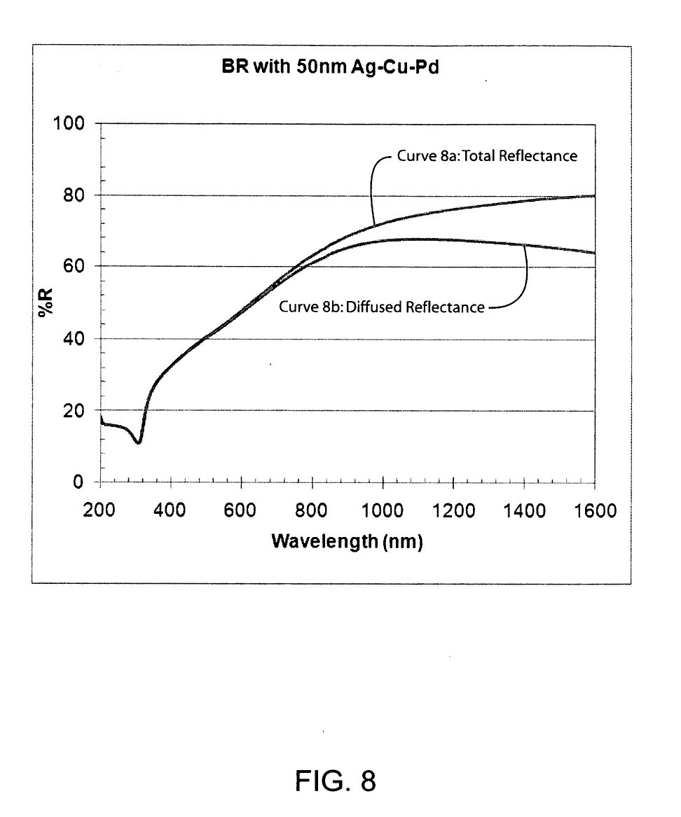

A back reflector 302 made on SS foil substrate 301 has a structure as shown in FIG. 3. comprising (i) a first metal layer 303 of a textured aluminum layer of 300 nm thick with a random texture surface same as the Al-layer in example 1; (ii) a first barrier layer 304 of a ZnO layer with a thickness of 30 nm; (iii) a second metal silver alloy layer 305 of a Ag_{0.7}Cu_{0.2}Pd_{0.1}(70 at % Ag, 20% at Cu, 10% at Pd) with a thickness of 50 nm, formed on the first barrier layer, (iv) a second TCO barrier layer 306 of a ZnO layer with a thickness of 650 nm, formed on the second metal layer. FIG. 8 shows a total reflection spectrum (Curve 8a) and a diffused reflection spectrum (Curve 8b) for a BR having the above described structure SS/300 nm-Al/30 nm-ZnO/50 nm-Ag_{0.7}Cu_{0.2}Pd_{0.1}. Curve 8a displays a reduced total reflectance of 30 to 65% in the wavelength range between 400 and 800 nm, which is dominated by copper absorption on the surface because of Ag—Cu˜Pd alloy, while a total reflectance of 65 to 80% in the wavelength range between 800 and 1400 nm. Curve 8b displays a corresponding low diffuse reflectance of 30 to 60% in the wavelength range between 400 and 800 nm, and a diffuse reflectance of 60 to 67% in the wavelength range between 800 and 1200 nm.

### Example 5

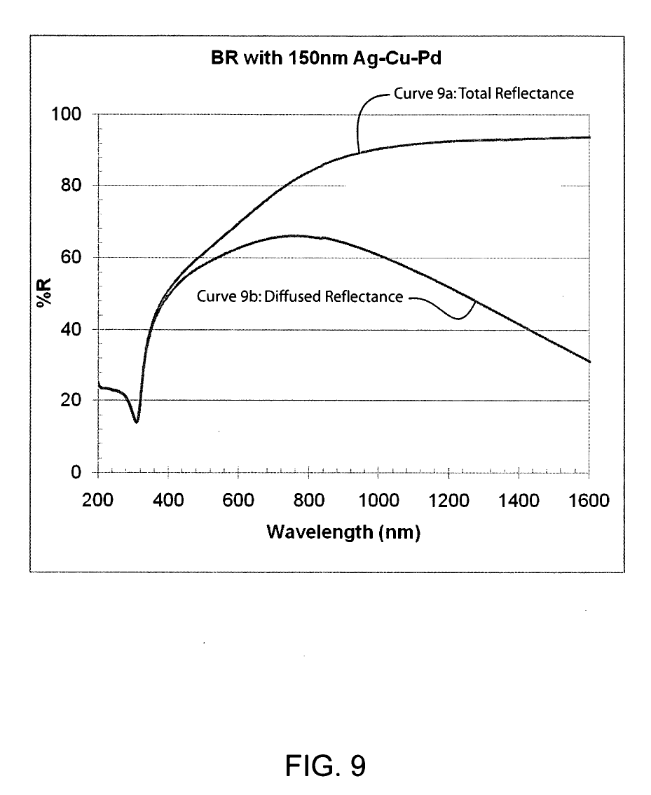

A back reflector made 302 on SS foil substrate 301 has a structure as shown in FIG. 3 comprising (i) a first metal layer 303 of a textured aluminum layer of 300 nm thick with a random texture surface same as the Al-layer in example 1; (ii) a first barrier layer 304 of a ZnO layer with a thickness of 30 nm; (iii) a second metal silver alloy layer 305 of a Ag_{0.7}Cu_{0.2}Pd_{0.1}(70 at % Ag, 20% at Cu, 10% at Pd) with a thickness of 150 nm, formed on the first barrier layer, (iv) a second TCO barrier layer 306 of a ZnO layer with a thickness of 650 nm, formed on the second metal layer. FIG. 9 shows a total reflection spectrum (Curve 9a) and a diffused reflection spectrum (Curve 9b) for a BR having the above described structure SS/300 nm-Al/30 nm-ZnO/150 nm-Ag_{0.7}Cu_{0.2}Pd_{0.1}. In comparison to the curves in FIG. 8, Curve 9a displays an improved total reflectance of 50 to 84% in the wavelength range between 400 and 800 nm, a high total reflectance of 84 to 92% in the wavelength range between 800 and 1200 nm. Curve 9b displays a corresponding diffuse reflectance of 50 to 65% in the wavelength range between 400 and 800 nm, and a diffuse reflectance of 65 to 50% in the wavelength range between 800 and 1200 nm.

### Example 6

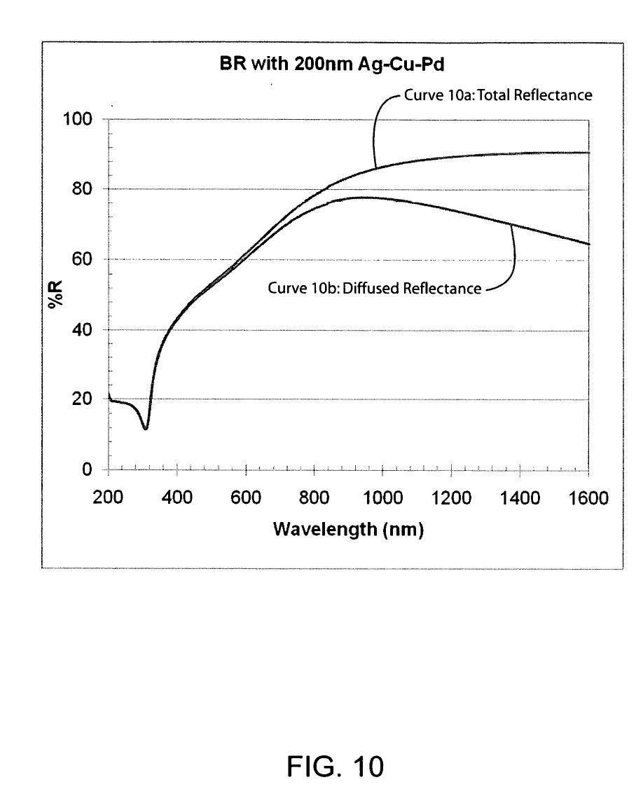

A back reflector 302 made on SS foil substrate 301 has a structure as shown in FIG. 3. comprising (i) a first metal layer 303 of a textured aluminum layer of 300 nm thick with a random texture surface same as the Al-layer in example 1; (ii) a first barrier layer 304 of a ZnO layer with a thickness of 30 nm; (iii) a second metal silver alloy layer 305 of a Ag_{0.7}Cu_{0.2}Pd_{0.1}(70 at % Ag, 20% at Cu, 10% at Pd) with a thickness of 200 nm, formed on the first barrier layer, (iv) a second TCO barrier layer 306 of a ZnO layer with a thickness of 650 nm, formed on the second metal layer. FIG. 10 shows a total reflection spectrum (curve 10a) and a diffused reflection spectrum (curve 11b) for a BR having the above described structure SS/300 nm-Al/30 nm-ZnO/200 nm-Ag_{0.7}Cu_{0.2}Pd_{0.1}. Curve 10a displays a total reflectance of 44 to 78% in the wavelength range between 400 and 800 nm, and a total reflectance of 78 to 89% in the wavelength range between 800 and 1200 nm. Curve 10b displays a corresponding diffuse reflectance of 44 to 74% in the wavelength range between 400 and 800 nm, and a diffuse reflectance of 74 to 78% in the wavelength range between 800 and 1200 nm.

### Example 7

An a-Si/a-SiGe/a-SiGe triple-junction solar cell materials 307 have been made on the back reflectors 302 as described in above examples 1-6, respectively. The corresponding solar PV modules per BR condition have also been fabricated & exposed to 1000 hours of damp-heat environmental testing (85° C., 85%). The corresponding solar module performances are summarized and compared in Table 1.

TABLE 1
PV module performances before and after 1000 hours of
damp-heat testing for solar PV modules per BR condition

| | Module | | | | |
|---|---|---|---|---|---|
| | Performances | Pmax | | | |
| BR Structure | and Changes | (Watt) | Voc (V) | Isc (A) | FF (%) |
| SS/300 nm- | Initial | 7.289 | 2.204 | 5.806 | 56.7 |
| Al/650 nm-ZnO | 1000 hrs damp | 7.119 | 2.207 | 5.746 | 56.1 |
| BR baseline | heat | | | | |
| | % in change | −2.8 | 0.2 | −1.3 | −1.2 |
| BR example 1 | Initial | 8.031 | 2.210 | 5.919 | 61.2 |
| with 50 nm-Ag | 1000 hrs damp | 5.071 | 1.896 | 5.724 | 46.7 |
| | heat | | | | |
| | % in change | −36.9 | −14.1 | −3.5 | −23.7 |
| BR example 2 | Initial | 8.181 | 2.192 | 6.049 | 61.7 |
| with 150 nm-Ag | 1000 hrs damp | 7.614 | 2.160 | 5.885 | 59.7 |
| | heat | | | | |
| | % in change | −6.9 | −1.4 | −2.7 | −3.3 |
| BR example 3 | Initial | 8.048 | 2.178 | 6.049 | 61.2 |
| with 200 nm-Ag | 1000 hrs damp | 7.223 | 2.118 | 5.829 | 58.3 |
| | heat | | | | |
| | % in change | −10.7 | −2.9 | −3.6 | −4.8 |
| BR example 4 | Initial | 7.726 | 2.203 | 6.001 | 58.2 |
| with 50 nm- | 1000 hrs damp | 6.824 | 2.135 | 5.846 | 54.5 |
| Ag_{0.7}Cu_{0.2}Pd_{0.1} | heat | | | | |
| | % in change | −11.8 | −3.0 | −2.6 | −6.5 |
| BR example 5 | Initial | 7.799 | 2.164 | 6.084 | 59.3 |
| with 150 nm- | 1000 hrs damp | 7.176 | 2.135 | 5.967 | 56.3 |
| Ag_{0.7}Cu_{0.2}Pd_{0.1} | heat | | | | |
| | % in change | −8.0 | −1.3 | −1.9 | −5.0 |
| BR example 6 | Initial | 7.680 | 2.165 | 6.102 | 58.1 |
| with 200 nm- | 1000 hrs damp | 6.806 | 2.110 | 5.913 | 55.0 |
| Ag_{0.7}Cu_{0.2}Pd_{0.1} | heat | | | | |
| | % in change | −11.3 | −2.4 | −3.0 | −5.1 |

The data in Table 1 suggest that a solar module made from Ag BR (BR examples 1-3) has ˜10% higher initial power output Pmax than those made from Al-BR, and a solar module made from Ag_{0.7}Cu_{0.2}Pd_{0.1}-BR (BR examples 4-5) has ˜5% higher initial power output Pmax than those made from Al-BR.

The data in Table 1 also suggest that modules made with baseline Al BR are less susceptible to degradation caused by damp heat than modules fabricated with any of the Ag— & Ag_{0.7}Cu_{0.2}Pd_{0.1} BR structure. However, increasing the Ag thickness of Ag-BR in modules from 50 nm towards 200 nm seems to mitigate degradation in damp heat; for the 150 nm-Ag BR structure the degradation rate stays after ˜1000 h of damp heat exposure below 10%, for 200 nm-Ag BR the rate is <12%.

Modules made from Ag_{0.7}Cu_{0.2}Pd_{0.1} BR show degradation rates being also below 12% for the BR structure of BR examples 4-6.

Alloying Ag-BR with Pd has a beneficial effect on the degradation rate of the device; this can be understood because PdO formation occurs spontaneously on the BR-surface: the PdO film is now inhibiting the Ag⁺ migration so that slower degradation rates can be observed.

The above detailed description of the present invention is given for explanatory purposes. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

I claim:

1. A thin-film photovoltaic device comprising:
a substrate;
a back reflector deposited over said substrate, said back reflector having a textured metal layer, a highly-reflective metal layer, and a first barrier layer positioned between the textured layer and the highly-reflective layer;
a thin-film semiconductor solar material positioned on said back reflector;
a front contact TCO layer positioned on said semiconductor material; and
a front contact electrode grid positioned on said front TCO layer.

2. The device of claim 1, further comprising a second TCO barrier layer positioned on the side of the highly-reflective metal layer that is spaced apart from the first barrier layer and wherein said textured layer comprises a textured metal or metal alloy layer and said a highly-reflective layer comprises a metal or metal alloy layer.

3. The device of claim 1, wherein said thin-film semiconductor solar material includes at least one n-i-p junction formed of amorphous silicon.

4. The device of claim 2, wherein said textured metal layer is comprised of a metal or a metal alloy which is different from the metal or metal alloy which comprises the highly reflective layer.

5. The device of claim 2, wherein said textured metal or alloy layer is formed of material from the group consisting preferably from aluminum, aluminum alloys, zinc, zinc alloys, copper, copper alloys, and combinations thereof.

6. The device of claim 2, wherein said textured metal or metal alloy layer has a random or periodic texture length in a range from about 100 nm to about 2000 nm, a random or periodic texture height in a range from about 50 nm to about 1000 nm, and an Rᵣₘₛ, surface roughness in a range of from about 1 nm to about 1000 nm.

7. The device of claim 2, wherein said first barrier layer is a zinc oxide barrier layer with a thickness from about 10 nm to about 200 nm.

8. The device of claim 2, wherein said highly-reflective metal or alloy layer is silver or a silver alloy and has a thickness from about 30 to about 500 nm.

9. The device of claim 2, wherein said second TCO barrier layer is a ZnO layer with a thickness from about 100 to about 4000 nm.

10. The device of claim 2, wherein said back reflector has a total reflectance of about 80% to about 98% in the wavelength range from 500 to 1000 nm of the electromagnetic spectrum.

11. The device of claim 6, wherein said Rᵣₘₛ surface roughness is in the range from about 40 nm to about 400 nm.

12. The device of claim 7, wherein said first barrier layer is ZnO and has a thickness from about 10 to about 80 nm thick.

13. The device of claim 8, wherein said highly reflective layer is silver alloyed with Pd and Cu.

14. The device of claim 10, wherein said back reflector has a diffuse reflectance equal to or greater than 70% in the wavelength range from 500 to 1000 nm of the electromagnetic spectrum.

15. The device of claim 13, wherein said back reflector has a total reflectance greater than 65% in the wavelength range from 800 to 1400 nm and a diffuse reflectance of greater than 30% in the wavelength range from 400 to 1200 nm of the electromagnetic spectrum.

16. The device of claim 14, wherein said back reflector has a diffuse reflectance equal to or greater than 80% in the wavelength range from 500 to 1000 nm of the electromagnetic spectrum.

17. The device of claim 15, wherein said diffuse reflectance is equal to or greater than 44% in all portions of the wavelength range from 400 to 1200 nm of the electromagnetic spectrum.

18. The device of claim 17, wherein said diffuse reflectance is equal to or greater than 50% in all portions of the wavelength range from 400 to 1200 nm of the electromagnetic spectrum.

19. A thin-film photovoltaic device comprising:
a stainless steel substrate;
a back reflector deposited over said substrate, said back reflector having a textured metal or metal alloy layer, a highly-reflective silver or silver alloy layer, a first barrier layer positioned between the textured layer and the highly-reflective layer; and a second TCO barrier layer positioned on the side of the highly-reflective metal layer that is spaced apart from the first barrier layer, wherein the back reflector has a total reflectance greater than 70% in the wavelength range from 800 to 1200 nm of the electromagnetic spectrum;
an amorphous silicon thin-film semiconductor solar material positioned on said back reflector;
a front contact TCO layer positioned on said semiconductor material;
a front contact electrode grids positioned on said front TCO layer and;
wherein the photovoltaic device produces a stable power output that does not lose more than 12% of its initial maximum power output.

20. The device of claim 19, wherein the textured metal or metal alloy layer has an Rᵣₘₛ surface roughness from about 100 to about 400 nm.
